(19) United States
(12) Patent Application Publication
(10) Pub. No.: US 2025/0040151 A1
(43) Pub. Date: Jan. 30, 2025

(54) SWITCH DEVICE AND MEMORY

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: Min ZHU, Shanghai (CN); Zhitang SONG, Shanghai (CN); Jiabin SHEN, Shanghai (CN); Shujing JIA, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 18/715,123

(22) PCT Filed: Feb. 23, 2022
(86) PCT No.: PCT/CN2022/077349

§ 371 Date: May 31, 2024

(30) Foreign Application Priority Data
Dec. 7, 2021 (CN) 2021115120580

(51) Int. Cl. H10B 63/00

(52) U.S. Cl. CPC H10B 63/24

(57) ABSTRACT

The switch device comprises a lower electrode, an upper electrode, and a switch material layer disposed between the lower electrode and the upper electrode. When the switch device is in an on state, the switch material layer is in a liquid state and has a bandgap of 0; when the switch device is in an off state, the switch material layer is in a crystalline state, and a Schottky barrier is formed between the switch material layer and the upper electrode, as well as between the switch material layer and the lower electrode. The switch device employs the crystalline-liquid-crystalline phase change mechanism of the switch material, and can drive memory units, such as phase change memory units, resistive memory units, ferroelectric memory units, magnetic memory units, and the like, thereby enabling high-density three-dimensional information storage.

### FIELD OF THE INVENTION

The present disclosure relates to the technical field of micro-nano electronics, in particular, to a switch device and a memory.

### BACKGROUND OF THE INVENTION

The booming development of emerging technologies such as artificial intelligence and the Internet of Things (IoT) has led to an exponential growth in data output, posing a great challenge to existing memories. Currently, the transistor has been miniaturized to 2-3 nanometers, which is close to its physical limit. Therefore, dimensional enhancement is required to develop high-density three-dimensional stacked memory devices with increased storage density.

In three-dimensional memories, a switch device is needed on the storage layer to avoid the effects of cross-talk. The switch device is capable of controlling whether a unit stores information. When the electrical signal applied to the switch device is significantly below the activation threshold, the switch device remains off, preventing the electrical signal from operating on the storage unit. When the applied electrical signal exceeds the activation threshold, the switch device turns on, causing the material to transit to a low-resistance state, allowing the electrical signal to directly act on the storage unit to perform the storage operation. Upon removal of the applied electrical signal, the switch material spontaneously reverts from the low-resistance state to the high-resistance state, thereby preventing leakage current from affecting the device unit. The available switch devices include metal-oxide-semiconductor transistors, diodes, conductive bridge threshold switches, metal-insulator transition switches, ovonic threshold switches (OTS), and the like.

These existing switches have many limitations, for example, the leakage current of the metal-oxide-semiconductor transistors increases significantly during the miniaturization process, and the on-state current of the conducive bridge switches is in the microampere order, which is not able to meet the requirements of new types of memories. The ovonic threshold switches, which simultaneously have low leakage conductance and high on-state current, need to be maintained in the amorphous state to function properly. However, its crystallization temperature is often lower than the post-annealing temperature in CMOS processes. To further increase the crystallization temperature, toxic substances such as As need to be doped, which is not conducive to sustainable development.

Therefore, how to develop a switch material and a switch unit with high thermal stability has become an urgent technical problem to be solved in the field.

### SUMMARY OF THE INVENTION

The present disclosure provides a switch device, comprising a lower electrode, an upper electrode, and a switch material layer disposed between the lower electrode and the upper electrode,
where the switch material layer comprises at least one element of Te, Se, and S;
when the switch device is in an on state, the switch material layer is in a liquid state and has a bandgap of 0;
when the switch device is in an off state, the switch material layer is in a crystalline state, the switch material layer and the upper electrode form a Schottky barrier, and the switch material layer and the lower electrode form a Schottky barrier.

Optionally, when the applied voltage is greater than a threshold voltage, the switch material layer is melted into the liquid state under the action of Joule heat, so that the switch device is turned on; and when the applied voltage is withdrawn or when the applied voltage is less than the threshold voltage, the switch material layer recrystallizes spontaneously, so that the switch device is turned off.

Optionally, the switch device has a ovonic threshold switching characteristic.

Optionally, the switch device has an on/off current ratio ranging from 1×10¹ to 9.9×10⁸ and a switching speed faster than 200 ns.

Optionally, the switch material has any of the above switching characteristics after being annealed at a temperature higher than 400° C.

Optionally, the switch material layer further comprises at least one of the elements of Ge, Si, Al, Be, Mg, Ca, Sr, Ba, and Mn.

Optionally, the general chemical formula of the switch material layer is (TeₓSe_{y}S_{z})_{1-a-b}MₐN_{b}, wherein M and N are different elements, M is selected from the elements of Ge, Si, Al, Be, Mg, Ca, Sr, Ba, and Mn, and N is selected from the elements of Ge, Si, Al, Be, Mg, Ca, Sr, Ba, and Mn; x, y, z, a, and b represent atomic contents and x+y+z=1, 0≤x≤1, 0≤y≤1, 0≤z≤1, 0<a+b<1, 0≤a≤0.5, 0≤b≤0.5.

Optionally, the general chemical formula of the switch material layer is GeₛTe₁₀₀₋ₛ, wherein s is an atomic content and 1≤s≤15.

Optionally, the thickness of the switch material layer ranges from 0.2 nm to 200 nm.

Optionally, the thickness of the switch material layer is less than 2 nm.

Optionally, the switch material layer has an atomic scale uniformity.

Optionally, the lower electrode comprises at least one of TiN, TaN, W, WN, and TiNSi; and the upper electrode comprises at least one of TiN, TaN, W, WN, and TiNSi.

Optionally, a diameter or an equivalent circular diameter of the switch material layer ranges from 0.4 nm to 500 nm.

The present disclosure also provides a memory, comprising multiple gated memory cells, wherein each gated memory cell comprises a gated unit and a storage unit, the gated unit is electrically connected to the storage unit to drive the storage unit, and the gated unit comprises any one of the foregoing switch devices.

Optionally, the storage unit is selected from a phase change storage unit, a resistive storage unit, a ferroelectric storage unit, and a magnetic storage unit.

Optionally, the plurality of gated memory cells form a crossbar memory array or a vertical memory array.

As described above, the switch device of the present disclosure includes a lower electrode, an upper electrode, and a switch material layer disposed between the lower electrode and the upper electrode. The switch device employs the crystalline-liquid-crystalline phase change mechanism of the switch material. When the applied voltage is less than a threshold voltage (turn-on voltage), the Schottky barrier formed between the crystalline switch material layer and the electrodes suppresses the off-state leakage currents. When the applied voltage exceeds the threshold voltage (turn-on voltage), the generated Joule heat melts the crystalline switch layer. In its liquid state, the switch material has a bandgap of zero and exhibits metallic-like resistivity, causing the Schottky barrier to disappear and a significant on-state current to flow. Upon removal of the applied voltage, the liquid switch material quickly recrystallizes, making the device revert to its off-state, restoring the Schottky barrier, and effectively reducing the off-state leakage conductance current. The switch device of the present disclosure has the advantages of large on-state current, small leakage current, small threshold voltage, high unit consistency, compatibility with CMOS process, good thermal stability, simple composition, low toxicity, and the ability to be highly miniaturized, etc. It can drive memory units, such as phase change memory units, resistive memory units, ferroelectric memory units, magnetic memory units, and the like, thereby enabling high-density three-dimensional information storage.

### BRIEF DESCRIPTION OF DRAWINGS

FIG. 1 shows a schematic cross-sectional diagram of the switch device of the present disclosure.

FIG. 2 shows a DC current-voltage profile of the switch device of the present disclosure.

FIG. 3 shows a pulse voltage-current profile of the switch device of the present disclosure.

FIG. 4 shows a transmission electron microscopy image of the switch device in an off state of the present disclosure.

FIG. 5 shows an enlarged view of the area shown by the dashed box in FIG. 4.

FIG. 6 shows a Fourier transform diagram of the area shown by the dashed box in FIG. 4.

### REFERENCE NUMERALS

1 Lower electrode
2 Switch material layer
3 Upper electrode

### DETAILED DESCRIPTION OF THE INVENTION

The following illustrates the embodiments of the present disclosure by means of particular specific examples, and other advantages and effects of the present disclosure can be readily understood by those skilled in the art according to the contents disclosed in this specification. The present disclosure may be implemented or applied in various other specific embodiments, and the details in this specification may be modified or changed in various ways based on different views and applications without departing from the spirit of the present disclosure.

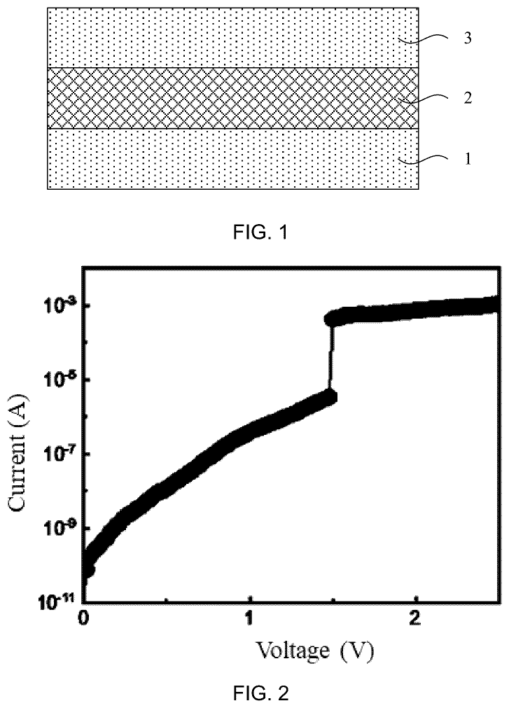

Please refer to FIGS. 1 to 6. It should be noted that the drawings provided in the embodiments are merely schematic to illustrate the basic concept of the present disclosure, and only the components related to the present disclosure are shown in the drawings. The drawings are not drawn in accordance with the number, shapes, and sizes of components in actual implementation, and the configuration, number, and proportion of the components may be changed arbitrarily, additionally, the layout of the components may be more complex.

### Embodiment 1

In this embodiment, a switch device is provided, and FIG. 1 shows a schematic cross-sectional diagram of the switch device. The switch device comprises a lower electrode 1, an upper electrode 3, and a switch material layer 2 disposed between the lower electrode 1 and the upper electrode 3, wherein the switch material layer 2 comprises at least one element of tellurium (Te), selenium (Se), and sulfur(S).

Specifically, the switch material layer 2 may be made of the simple substance of Te, Se, or S; compounds, mixtures, or alloys comprising any two of Te, Se, and S; or compounds, mixtures, or alloys comprising Te, Se, and S.

Specifically, in order to reduce the leakage conductance, at least one of the elements of Ge, Si, Al, Be, Mg, Ca, Sr, Ba, and Mn may be doped in the switch material layer 2 comprising Te and/or Se and/or S.

As an example, the general chemical formula of the switch material layer is (TeₓSe_{y}S_{z})_{1-a-b}MₐN_{b}, wherein M and N are different elements, M is selected from the elements of Ge, Si, Al, Be, Mg, Ca, Sr, Ba, and Mn, and N is selected from the elements of Ge, Si, Al, Be, Mg, Ca, Sr, Ba, and Mn. x, y, z, a, and b represent atomic contents, and x+y+z=1, 0≤x≤1, 0≤y≤1, 0≤z≤1, 0≤a+b<1, 0≤a≤0.5, 0≤b≤0.5.

As an example, the general chemical formula of the switch material layer is GeₛTe₁₀₀₋ₛ, wherein s is an atomic content and 1≤s≤15.

As an example, the switch material layer 2 may be formed by sputtering, evaporation, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), atomic layer deposition (ALD), or other suitable methods.

Specifically, the switch material layer 2 of the switch device is in a crystalline state during the deposition process or when the switch device is in the off state. When the applied voltage is less than a threshold voltage (turn-on voltage), the Schottky barrier formed between the crystalline switch material and the electrodes suppresses the off-state leakage currents. When the applied voltage exceeds the threshold voltage (turn-on voltage), the generated Joule heat melts the crystalline switch material. In its liquid state, the switch material has a bandgap of zero and exhibits metallic-like resistivity, causing the Schottky barrier to disappear and a significant on-state current to flow. Upon removal of the applied voltage or when the applied voltage becomes less than the threshold voltage, the liquid switch material quickly recrystallizes, making the device revert to its off state, restoring the Schottky barrier, and effectively reducing the off-state leakage conductance current.

Specifically, the switch device is a two-terminal device and has a ovonic threshold switching characteristic. The switch device has an on/off current ratio ranging from 1×10¹ to 9.9×10⁸, indicating that the on/off current ratio spans 1 to 8 orders of magnitude. The switch device has a switching speed faster than 200 ns.

Specifically, the switch material has any of the above switching characteristics after being annealed at a temperature higher than 400° C.

Specifically, the thickness of the switch material layer 2 can be set according to actual needs, for example, the thickness of the switch material layer 2 ranges from 0.2 nm to 200 nm. In this embodiment, the thickness of the switch material layer 2 is preferably less than 2 nm, so that when the switch device is in the off state, the bandgap of the switch material layer 2 is increased, which is favorable to reducing the leakage conductance current of the device.

As an example, the diameter or equivalent circular diameter of the switch material layer 2 ranges from 0.4 nm to 500 nm, and further, from 0.4 nm to 60 nm or from 0.4 nm to 10 nm, meaning that the switch device is capable of being miniaturized to 10 nm˜0.4 nm.

Specifically, the lower electrode 1 includes, but is not limited to, at least one of TiN, TaN, W, WN, and TiNSi; and the upper electrode 3 includes, but is not limited to, at least one of TiN, TaN, W, WN, and TiNSi. The lower electrode 1 and the upper electrode 3 may be formed by sputtering, evaporation, chemical vapor deposition (CVD), plasma enhanced chemical vapor deposition (PECVD), low pressure chemical vapor deposition (LPCVD), metal organic chemical vapor deposition (MOCVD), molecular beam epitaxy (MBE), atomic vapor deposition (AVD), atomic layer deposition (ALD), or other suitable methods.

Specifically, the switch material layer 2 has an atomic scale uniformity and forms a perfect interface with TiN, TaN, W, WN, or TiNSi electrodes without significant interdiffusion, thus leading to stable performance and good inter-unit consistency of the switch device.

The switching performance of the switch device of the present disclosure is illustrated below, where the switch device is made of GeTe₁₆ (equivalent to Ge5.88Te94.02). FIG. 2 shows a DC current-voltage profile of the switch device, it can be seen that the GeTe₁₆ switch unit has an on-current of Iₒₙ≥10⁻⁴ A, a leakage current of I_{off}≤10⁻⁶ A, an on/off ratio of at least 2 orders of magnitude, and a threshold voltage Vₜₕ≤2 V.

Preferably, in this embodiment, the GeTe₁₆ switch unit has an on-current of Iₒₙ≥10⁻³ A, a leakage current of I_{off}≤10⁻⁹ A, an on/off ratio of at least 5 orders of magnitude, and a lifetime of more than 10⁸.

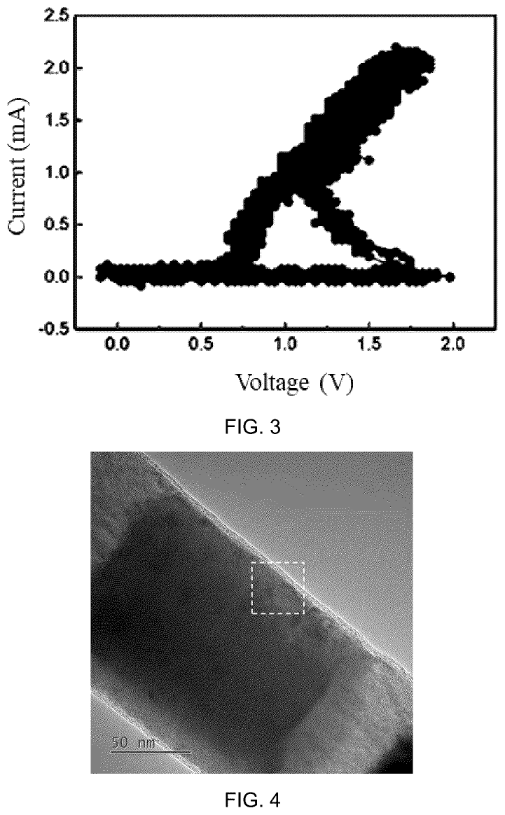

FIG. 3 shows a pulse voltage-current profile of the switch device. When the voltage applied to the switch device is less than 1.75 V, the switch device is in the off state, and the current is almost zero. When the voltage applied to the switch device exceeds the threshold voltage of 1.75 V, the switch unit is instantly turned on, and the current passing through the switch device rapidly increases to 1.0 mA. When the voltage applied to the switch device is removed (voltage now is 0.75 V), the switch device is instantly turned off, and the current passing through the switch device rapidly decreases, thus the switch device becomes in a high-resistance state.

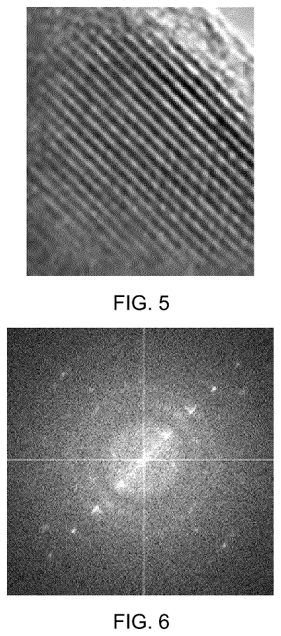

Please refer to FIGS. 4 to 6, where FIG. 4 shows a transmission electron microscopy image of the switch device in the off state, FIG. 5 shows an enlarged view of the area shown by the dashed box in FIG. 4, and FIG. 6 shows a Fourier transform image of the area shown by the dashed box in FIG. 4. As seen in FIG. 4 and FIG. 5, when the switch device is in the off state, the GeTe₁₆ layer is in a polycrystalline state, and the diffraction spots shown in FIG. 6 further demonstrate that GeTe₁₆ is in a crystalline state. In addition, it is seen that the GeTe₁₆ switch material has an atomic scale uniformity and forms a perfect interface with the TiN electrode without significant interdiffusion. Due to the high Schottky barrier formed by the crystalline GeTe₁₆ with the electrodes, the resistance of the device is high and the device is in the off state.

The switch device in this embodiment employs the crystalline-liquid-crystalline phase change mechanism of the switch material. When the applied voltage is less than a threshold voltage (turn-on voltage), the Schottky barrier formed between the crystalline switch material and the electrodes suppresses the off-state leakage currents. When the applied voltage exceeds the threshold voltage (turn-on voltage), the generated Joule heat melts the crystalline switch layer. In its liquid state, the switch material has a bandgap of zero and exhibits metallic-like resistivity, causing the Schottky barrier to disappear and a significant on-state current to flow. Upon removal of the applied voltage, the liquid switch material quickly recrystallizes, making the device revert to its off state, restoring the Schottky barrier, and effectively reducing the off-state leakage conductance current. The switch device of this embodiment has the advantages of large on-state current, small leakage current, small threshold voltage, high unit consistency, compatibility with CMOS process, good thermal stability, simple composition, low toxicity, and the ability to be highly miniaturized, etc.

### Embodiment 2

A memory is provided in this embodiment, wherein the memory comprises multiple gated memory cells. Each gated memory cell comprises a gated unit and a storage unit, the gated unit is electrically connected to the storage unit to drive the storage unit, and the gated unit comprises a switch device as described in embodiment 1. The switch device has the advantages of large on-state current, small leakage current, good thermal stability, simple composition, nontoxicity, high switching speed, etc. Additionally, it can efficiently drive memory units, such as phase change memory units, resistive memory units, ferroelectric memory units, or magnetic memory units.

As an example, the gated memory cells can form a crossbar memory array or a vertical memory array, thereby realizing high-density three-dimensional information storage. The crossbar memory array includes multiple word lines and multiple bit lines arranged in a cross pattern, with the gated memory cells located at the intersections of the word lines and bit lines. The vertical memory array contains multiple bit lines and multiple selection lines arranged in a cross pattern, with the gated memory cells located at the intersections of the bit lines and selection lines. Above the selection lines, there are multiple word line layers stacked at intervals in the vertical direction, and there are multiple storage units on each gated unit to form a memory string.

In summary, the switch device of the present disclosure includes a lower electrode, an upper electrode, and a switch material layer disposed between the lower electrode and the upper electrode. The switch device employs the crystalline-liquid-crystalline phase change mechanism of the switch material. When the applied voltage is less than a threshold voltage (turn-on voltage), the Schottky barrier formed between the crystalline switch material and the electrodes suppresses the off-state leakage currents. When the applied voltage exceeds the threshold voltage (turn-on voltage), the generated Joule heat melts the crystalline switch layer. In its liquid state, the switch material has a bandgap of zero and exhibits metallic-like resistivity, causing the Schottky barrier to disappear and a significant on-state current to flow. Upon removal of the applied voltage, the liquid switch material quickly recrystallizes, making the device revert to its off-state, restoring the Schottky barrier, and effectively reducing the off-state leakage conductance current. The switch device of the present disclosure has the advantages of large on-state current, small leakage conductance current, small threshold voltage, high unit consistency, compatibility with CMOS process, good thermal stability, simple composition, low toxicity, and the ability to be highly miniaturized, etc. It can drive memory units, such as phase change memory units, resistive memory units, ferroelectric memory units, magnetic memory units, and the like, thereby enabling high-density three-dimensional information storage. Therefore, the present disclosure effectively overcomes the shortcomings of the prior art and has high industrial utilization value.

The above embodiments are only exemplary to illustrate the principle and effects of the present disclosure, and are not intended to limit the present disclosure. Any person familiar with the art may modify or change the above embodiments without violating the spirit and scope of the present disclosure. Therefore, all equivalent modifications or changes made by persons having ordinary knowledge of the art without departing from the spirit and technical ideas disclosed in the present disclosure shall still be covered by the claims of the present disclosure.

1. A switch device, comprising a lower electrode, an upper electrode, and a switch material layer disposed between the lower electrode and the upper electrode,
wherein the switch material layer comprises at least one element of Te, Se, and S;
when the switch device is in an on state, the switch material layer is in a liquid state and has a bandgap of 0;
when the switch device is in an off state, the switch material layer is in a crystalline state, the switch material layer and the upper electrode form a Schottky barrier, and the switch material layer and the lower electrode form a Schottky barrier.

2. The switch device according to claim 1, wherein when an applied voltage is greater than a threshold voltage, the switch material layer is melted into the liquid state under the action of Joule heat, so that the switch device is turned on; and when the applied voltage is removed or when the applied voltage is less than the threshold voltage, the switch material layer recrystallizes spontaneously, so that the switch device is turned off.

3. The switch device according to claim 1, wherein the switch device has a ovonic threshold switching characteristic.

4. The switch device according to claim 1, wherein the switch device has an on/off current ratio ranging from 1×10¹ to 9.9×10⁸ and a switching speed faster than 200 ns.

5. The switch device according to claim 1, wherein the switch material has a switching characteristics of claim 2 after being annealed at a temperature higher than 400° C.

6. The switch device according to claim 1, wherein the switch material layer further comprises at least one of the elements of Ge, Si, Al, Be, Mg, Ca, Sr, Ba, and Mn.

7. The switch device according to claim 6, wherein a general chemical formula of the switch material layer is (TeₓSe_{y}S_{z})_{1-a-b}MₐN_{b}, wherein M and N are different elements, M is selected from the elements of Ge, Si, Al, Be, Mg, Ca, Sr, Ba, and Mn, and N is selected from the elements of Ge, Si, Al, Be, Mg, Ca, Sr, Ba, and Mn; x, y, z, a, and b represent atomic contents and x+y+z=1, 0≤x≤1, 0≤y≤1, 0≤z≤1, 0≤a+b<1, 0≤a≤0.5, 0≤b≤0.5.

8. The switch device according to claim 6, wherein a general chemical formula of the switch material layer is GeₛTe₁₀₀₋ₛ, wherein s is an atomic content and 1≤s≤15.

9. The switch device according to claim 1, wherein a thickness of the switch material layer ranges from 0.2 nm to 200 nm.

10. The switch device according to claim 9, wherein the thickness of the switch material layer is less than 2 nm.

11. The switch device according to claim 1, wherein the switch material layer has an atomic scale uniformity.

12. The switch device according to claim 1, wherein the lower electrode comprises at least one of TiN, TaN, W, WN, and TiNSi; and the upper electrode comprises at least one of TiN, TaN, W, WN, and TiNSi.

13. The switch device according to claim 1, wherein a diameter or an equivalent circular diameter of the switch material layer ranges from 0.4 nm to 500 nm.

14. A memory, comprising a plurality of gated memory cells, wherein each of the plurality of gated memory cell comprises a gated unit and a storage unit, the gated unit is electrically connected to the storage unit to drive the storage unit, wherein the gated unit comprises the switch device of claim 1.

15. The memory according to claim 14, wherein the storage unit is selected from a phase change storage unit, a resistive storage unit, a ferroelectric storage unit, and a magnetic storage unit.

16. The memory according to claim 14, wherein the plurality of gated memory cells form a crossbar memory array or a vertical memory array.
